(19) United States
(12) Patent Application Publication
(10) Pub. No.: US 2026/0223423 A1
(43) Pub. Date: Jul. 30, 2026

(54) Shape Control for Processing Silicon Carbide Semiconductor Wafers

(71) Applicant: Wolfspeed, Inc., Durham, NC (US)

(72) Inventors: Simon Bubel, Carrboro, NC (US); Yuri I. Khlebnikov, Raleigh, NC (US); Dinusha Priyadarshani Karunaratne, Cary, NC (US)

(21) Appl. No.: 19/041,649

(22) Filed: Jan. 30, 2025

(51) Int. Cl. H10D 62/832; H01L 21/04; H10D 62/53

(52) U.S. Cl. CPC H10D 62/8325; H10D 62/53; H10P 50/00

(57) ABSTRACT

An example method includes providing a silicon carbide semiconductor wafer having a first major surface and a second major surface. The example method includes performing a strain altering process to produce an altered strain state in the silicon carbide semiconductor wafer. The example method includes performing a fabrication process, wherein the fabrication process is a different type of process relative to the strain altering process, wherein the altered strain state at least partially compensates for stress or strain induced in the silicon carbide semiconductor wafer in the fabrication process.

### FIELD

The present disclosure relates generally to methods for shape control of a semiconductor workpiece, such as silicon carbide semiconductor workpieces for fabrication of semiconductor devices.

### BACKGROUND

Power semiconductor devices are used to carry large currents and support high voltages. A wide variety of power semiconductor devices are known in the art including, for example, transistors, diodes, thyristors, power modules, discrete power semiconductor packages, and other devices. For instance, example semiconductor devices may be transistor devices such as Metal Oxide Semiconductor Field Effect Transistors (“MOSFET”), bipolar junction transistors (“BJTs”), Insulated Gate Bipolar Transistors (“IGBT”), Gate Turn-Off Transistors (“GTO”), junction field effect transistors (“JFET”), high electron mobility transistors (“HEMT”) and other devices. Example semiconductor devices may be diodes, such as Schottky diodes or other devices.

Power semiconductor devices may be packaged into various semiconductor device packages, such as discrete semiconductor device packages and power modules. Power modules may include one or more power devices and other circuit components and can be used, for instance, to dynamically switch large amounts of power through various components, such as motors, inverters, generators, and the like.

Semiconductor devices may be fabricated from wide bandgap semiconductor materials, such as silicon carbide and/or Group III-nitride based semiconductor materials. The fabrication process for power semiconductor devices may require processing of wide bandgap semiconductor wafers, such as silicon carbide semiconductor wafers.

### SUMMARY

Aspects and advantages of embodiments of the present disclosure will be set forth in part in the following description, or can be learned from the description, or can be learned through practice of the embodiments.

In an aspect, the present disclosure provides an example method. In some implementations, the example method includes providing a silicon carbide semiconductor wafer having a first major surface and a second major surface. In some implementations, the example method includes performing a strain altering process to produce an altered strain state in the silicon carbide semiconductor wafer. In some implementations, the example method includes performing a fabrication process, wherein the fabrication process is a different type of process relative to the strain altering process, wherein the altered strain state at least partially compensates for stress or strain induced in the silicon carbide semiconductor wafer in the fabrication process.

In an aspect, the present disclosure provides an example method. In some implementations, the example method includes providing a silicon carbide semiconductor wafer having a first major surface and a second major surface. In some implementations, the example method includes performing a surface processing operation on the first major surface to produce an altered strain state of the wafer. In some implementations, the example method includes performing a deposition process on the second major surface. In some implementations, the example method includes performing an implantation process on the second major surface. In some implementations, the altered strain state at least partially compensates for a deformation induced by the deposition process or the implantation process.

In an aspect, the present disclosure provides an example silicon carbide semiconductor wafer. In some implementations, the example silicon carbide semiconductor wafer includes a first major surface and a second major surface. In some implementations, the example silicon carbide semiconductor wafer includes a strain altering portion on at least one of the first major surface or the second major surface, wherein the strain altering portion is configured to alter a strain state of the first major surface or the second major surface when the silicon carbide semiconductor wafer is exposed to a stimulus.

In an aspect, the present disclosure provides an example method. In some implementations, the example method includes performing a first process on the first major surface. In some implementations, the example method includes during performing of the first process, performing a second process on the second major surface, wherein the second process is a different type of process relative to the first process. In some implementations, one or more stresses induced or relieved by the first process are at least partially offset by one or more stresses induced or relieved by the second process.

In an aspect, the present disclosure provides an example method. In some implementations of the example method, the method includes providing a silicon carbide semiconductor wafer having a first major surface and a second major surface. In some implementations of the example method, the method includes performing a first process on the first major surface. In some implementations of the example method, the method includes performing a second process on the second major surface. In some implementations of the example method, the method includes wherein the first process and the second process induce balanced stresses on the silicon carbide semiconductor wafer, wherein the first process and the second process reduce deformation of the silicon carbide semiconductor wafer in one or more fabrication processes.

In an aspect, the present disclosure provides an example method. In some implementations, the example method includes providing a silicon carbide semiconductor wafer having a first major surface and a second major surface. In some implementations, the example method includes performing a strain altering process to produce an altered strain state in the silicon carbide semiconductor wafer by adding or reducing stress to the semiconductor wafer. In some implementations, the strain altering process is one or more of a surface processing operation, laser-based process, chemical process, or a thermal process.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts an example method according to aspects of the present disclosure.

FIG. 2 depicts an example method according to aspects of the present disclosure.

FIG. 3 depicts a shaped wafer according to aspects of the present disclosure.

FIG. 4 depicts an example method according to aspects of the present disclosure.

FIG. 5 depicts an example method according to aspects of the present disclosure.

FIG. 6 depicts a top view of a shaped wafer according to example aspects of the present disclosure.

FIG. 7 depicts a top view of a shaped wafer according to example aspects of the present disclosure.

FIG. 8 depicts a cross-sectional view of a shaped wafer according to aspects of the present disclosure.

FIGS. 9A through 9C depict a cross-sectional view of a shaped wafer according to aspects of the present disclosure.

FIG. 10 depicts a cross-sectional view of a shaped wafer according to aspects of the present disclosure.

FIGS. 11A through 11G depict example scan patterns according to aspects of the present disclosure.

Repeat use of reference characters in the present specification and drawings is intended to represent the same and/or analogous features or elements of the present invention.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations may be made to the embodiments without departing from the scope or spirit of the present disclosure. For instance, features illustrated or described as part of one embodiment may be used with another embodiment to yield a still further embodiment. Thus, it is intended that aspects of the present disclosure cover such modifications and variations.

Power semiconductor devices are often fabricated from wide bandgap semiconductor materials, such as silicon carbide or Group III-nitride based semiconductor materials (e.g., gallium nitride). Herein, a wide bandgap semiconductor material refers to a semiconductor material having a bandgap greater than 1.40 eV. Aspects of the present disclosure are discussed with reference to silicon carbide-based semiconductor structures as wide bandgap semiconductor structures. Those of ordinary skill in the art, using the disclosures provided herein, will understand that example embodiments of the present disclosure may be used with any semiconductor material, such as other wide bandgap semiconductor materials, without deviating from the scope of the present disclosure. Example wide bandgap semiconductor materials include silicon carbide and the Group III-nitrides.

Power semiconductor devices may be fabricated using epitaxial layers formed on a semiconductor workpiece, such as a silicon carbide semiconductor wafer. Power semiconductor device fabrication processes may include surface processing operations that are performed on the silicon carbide semiconductor wafer to prepare one or more surfaces of the silicon carbide semiconductor wafer for later processing steps, such as dopant implantation, formation of epitaxial layers, metallization, etc. Example surface processing operations may include grinding operations, lapping operations, and polishing operations.

Aspects of the present disclosure are discussed with reference to a semiconductor workpiece that is a semiconductor wafer that includes silicon carbide (“silicon carbide semiconductor wafer”) for purposes of illustration and discussion. Those of ordinary skill in the art, using the disclosures provided herein, will understand that aspects of the present disclosure can be used with other semiconductor workpieces. Other semiconductor workpieces may include carrier substrates, ingots, boules, polycrystalline substrates, monocrystalline substrates, bulk materials having a thickness of greater than 1 mm, such as greater than about 5 mm, such as greater than about 10 mm, such as greater than about 20 mm, such as greater than about 50 mm, such as greater than about 100 mm, to 200 mm, etc.

Semiconductor workpieces may be required to have specific wafer shape (e.g., bow warp, thickness variation, etc.) and/or surface attributes (e.g., surface roughness, usable area, or other parameters) for semiconductor device fabrication processes. As used herein, both wafer shape and surface attributes of a wafer will be referred to as shape parameters. Example shape parameters include global shape parameters such bow, warp, total thickness variation as well as local shape parameters, such as local thickness variation, site flatness front referenced surface least-squares reference plane range (SFQR). Shape parameters also include surface parameters, such as surface roughness.

Wafer bowing, warping, and the like occurs when one or more of the silicon face and the carbon face form surface deviation from a reference plane. Warp may be defined as the sum of maximum positive and maximum negative deviation from the reference plane, whereas bow may be defined as the maximum positive or negative deviation from the reference plane at the center of the wafer. Total thickness variation (TTV) may describe variations in evenness of the thickness of a wafer, or the difference between a thickest portion of a wafer and the thinnest portion of the wafer. Likewise, local thickness variation (LTV) may describe variations in evenness in a portion of the wafer, such as the difference between the thickest portion of a predefined area of the wafer and the thinnest portion of the same predefined area of the wafer. Site flatness front referenced surface least-squares reference plane range (SQFR) may determine a least-squares best-fit reference plane throughout the wafer and determine the difference between minimum and maximum surface features from the reference plane for predefined indexed locations of the wafer.

Various techniques may be used to measure bow of wafers according to embodiments disclosed herein. Such techniques include arrangements to correct for gravity-induced deformation or sagging of wafers. One such measurement technique, as described in the Semiconductor Equipment and Materials International (SEMI) standard MF1390 titled “Test Method for Measuring Warp on Silicon Wafers by Automated Non-Contact Scanning,” is used to correct for gravitational effects by comparing first wafer measurements with inverted second wafer measurements such that the difference between the two corresponds to gravitational effects. Other measurement techniques may be found in SEMI standard 3D4-0915 titled “Guide for Metrology for Measuring Thickness, Total Thickness Variation (TTV), Bow, Warp/Sori, and Flatness of Bonded Wafer Stacks,” which describes various gravity compensation techniques for horizontally and vertically supported wafers. In certain embodiments, such measurement techniques may include interferometry. In certain embodiments, measurement techniques may include the use of an optical flat that is used to determine flatness, or lack thereof, of wafers.

Aspects of the present disclosure refer to and/or claim a “surface roughness” of a surface. As used herein, unless otherwise specifically noted, the surface roughness is measured as “areal average roughness” Sa. When the present disclosure or claims refer to a surface having a surface roughness being within a range of values, a surface has a surface roughness in the range of values if any 1 millimeter by 1 millimeter area on the surface includes a surface roughness Sa within the specified range of values or if any 1 millimeter by 1 millimeter area on the surface includes a surface roughness Sz (maximum height) within the specified range of values.

As an example, a surface has a surface roughness in a range of 0.5 nm to 180 nm if any 1 millimeter×1 millimeter area on the surface has a surface roughness Sa in the range of 0.5 nanometers to 180 nanometers or if any 1 millimeter×1 millimeter area on the surface has a surface roughness Sz in the range of 0.5 nanometers to 180 nanometers. For the sake of clarity, it is not required that the entire surface have the surface roughness in the specified range of values. Only a single 1 millimeter×1 millimeter area on the surface is required to have a surface roughness in the specified range of values (e.g., either Sa or Sz) for the surface to be considered to have a surface roughness in the specified range of values.

Shape parameters may be required to meet uniformity specifications. For instance, and by non-limiting example, to undergo a planarization process, (e.g., CMP process) it may be desirable to have a flat workpiece where a peripheral portion of a workpiece and/or a central portion of a workpiece do not exhibit significant surface shape irregularities. A workpiece with high surface roughness or high shape irregularity may lead to increased processing time (e.g., for a CMP processes) and/or additional processing operations to bring a workpiece to acceptable shape parameter specifications, and/or may lead to increased material waste as portions of a workpiece having an irregular surface undergo disproportionate planarization as compared to a workpiece surface that is in-plane at a peripheral and/or central portions. That is, to uniformly produce a desired surface roughness across the entire workpiece, surface regions of the workpiece with out-of-plane bowing may undergo additional planarization in a CMP process.

Additionally, processes relying on optical properties of the workpiece, such as lithography or metrology processes, are dependent on shape parameters of the workpiece. For instance, semiconductor fabrication processes reliant on optical properties of the workpiece (e.g., lithography and metrology) typically require a flat wafer surface. Lithography and/or metrology processes may include limits on shape parameters such as bow, warp, total thickness variation, etc. to provide reliable and repeatable results or measurements. Localized shape properties, such as localized thickness variation, SFQR, etc. may also limit a lithography and/or metrology process.

Additionally, fabrication processes such as epitaxial film deposition, metal deposition, dopant implantation, or other thermal processes (e.g., thermal oxidation, annealing, dopant activation, curing of films or coatings, diffusion-reliant processes, etc.) on or adjacent to a workpiece surface may cause one or more surfaces of the workpiece to deform, potentially impacting the deposition process, thermal control of the surface during a process, and ultimately, device quality. For example, and by non-limiting example, a workpiece adhered to a chuck may lose contact between the workpiece and the chuck during a deposition or implantation process, which may be due to the surface of the workpiece that is adhered to the chuck deforming in response to damage or other forces on an opposing surface resulting from the deposition process or implantation process.

In addition to impacting the quality of the downstream process being performed on the workpiece surface (e.g., CMP, epitaxial film deposition, implantation, lithography, metrology, etc.), the shape of one or more workpiece surfaces that may deform resulting from previous processing operations may further exacerbate process control downstream. The workpiece may be deformed such that the surface of the workpiece exceeds a threshold of equipment constraints, which may limit the ability for a processing operation to be performed if the workpiece deforms beyond thresholds for robotic handling of the workpiece. Additionally, the shape or surface of a workpiece may be altered by internal stresses inherent to the crystal lattice formed by a crystal growth process, which may impact one or more fabrication processes. The deformation of one or more surfaces of a workpiece as the workpiece undergoes sequential processing steps impacts process quality, processing time, and could exceed equipment constraints, reducing throughput time, yield, and leading to increased material costs and/or waste.

Providing control over the shape or strain of a workpiece allows for the shape of the workpiece surface to be tuned to a process. Further, the ability to alter the strain or shape of a surface of a workpiece by way of a processing environment may enhance the process being performed on the workpiece without impacting upstream processing operations. According to some example aspects of the present disclosure, a strain altering process conducted on a workpiece may allow for stresses acting on and within (e.g., internal stresses) the workpiece to be altered during a processing operation, thereby producing a desired orientation or shape of the workpiece surface that is favorable to the process being conducted. That is, a staring altering process may induce an altered strain state in the workpiece that allows for desired shape control of a workpiece surface, for instance, to compensate for one or more stresses or strain induced in a workpiece in a subsequent fabrication process or prior fabrication process.

Accordingly, aspects of the present disclosure are directed to methods for processing (e.g., shaping, stressing, etc.) a semiconductor workpiece surface, for instance, in anticipation of future processing operations. In some examples, the strain altering process is a shaping process, such as a pre-shaping process, that is performed to compensate for stress, strain, and or shape changes in one or more downstream process operations. For instance, a subsequent fabrication process may modify a shape of a workpiece. A strain altering process may induce an altered strain state that at least partially compensates for stress or strain induced in a workpiece in a subsequent fabrication process (e.g., leading to the modified shape of the workpiece). A prior fabrication process may modify a shape of a workpiece. A strain altering process may induce an altered strain state that at least partially compensates for stress or strain induced in a workpiece in the prior fabrication process (e.g., leading to the modified shape of the workpiece). However, the strain altering processes and methods according to example aspects of the present disclosure can be conducted at, prior to, and/or before any stage of the fabrication process (e.g., wafer fabrication, device fabrication, surface processing, implantation, epitaxy, deposition, etch, etc.) without deviating from the scope of the present disclosure.

One example aspect of the present disclosure is directed to a method for processing a silicon carbide semiconductor workpiece. The method includes providing a silicon carbide semiconductor workpiece having a first major surface and a second major surface. The method includes altering a strain state in the silicon carbide semiconductor workpiece to modify a mechanical behavior of the silicon carbide semiconductor workpiece in a subsequent fabrication process. As used herein, “altering a strain state” or an “altered strain state” refers to changing or a change in strain state that may result in a change in shape or deformation of the workpiece. In some examples, the altered strain state may be a result of inducing stress or relieving stress. In some examples, the altered strain state may be sufficient to induce or cause deformation of a workpiece relative to a flat first major surface or flat second major surface such that either the first major surface or the second major surface exhibits a deformation of about 0.2 micrometers or greater relative to the largest axis of the surface.

In some examples, the altered strain state is a result of a stress or stress gradient applied to the silicon carbide semiconductor workpiece. In some examples, the altered strain state results from a compressive stress applied in a radial direction toward a center portion of the first major surface or the second major surface. In some examples, the altered strain state results from a compressive stress applied in a radial direction toward a peripheral portion of the first major surface or the second major surface. In some examples, the altered strain state results from tensile stress applied in a radial direction toward a peripheral portion of the first major surface or the second major surface. In some examples, the altered strain state results from a compressive stress in a circumferential direction on the first major surface or the second major surface. In some examples, the altered strain state results from a tensile stress in a circumferential direction on the first major surface or the second major surface. In some examples, the altered strain state results from altered stress in an axial direction of the silicon carbide semiconductor workpiece.

In some examples, the altered strain state is configured to at least partially offset a deformation of the silicon carbide semiconductor workpiece in the subsequent fabrication process. In some examples, the altered strain state is induced by an external force, a fluid pressure, radiation exposure, a temperature change, a temperature gradient, exposure to an electrostatic field, or exposure to a magnetic field. In some examples, the altered strain state is induced by a stress altering operation performed on at least a portion of the first major surface or the second major surface.

As used herein, a stress may include a tensile stress or a compressive stress exhibited by the material (e.g., internal stresses), or acting on the material surface. Tensile stress may describe a stress resulting from a pushing or pulling force of a material outward. As used herein, compression or a compressive stress may describe a stress that shortens, contracts, or results from a pushing or pulling force of a material inward.

As used herein, a bulk stress or a residual stress may refer to internal stress that may be imparted in the workpiece during formation (e.g., crystal growth processes) or induced in a processing operation (e.g., stress resulting from a separation process that removes a wafer from a boule, for example). That is, internal stress relates to the potential energy stored within a material due to the presence of a bulk stress or residual stress, which may be inherent to the crystal structure and/or imparted in a processing operation. As used herein, a strain altering portion may include a portion or surface of a workpiece that has undergone a strain altering process to induce an altered strain state for the workpiece or in a subsurface region in close proximity to a surface of the workpiece. A strain altering portion may include a subsurface portion or a surface of the workpiece that has undergone a strain altering process to alter bulk stresses or internal stresses to induce an altered strain state of the workpiece.

In some examples, a shaping process produces a strain altering portion having a thickness in a range of at least about 0.01 micrometer to about 1 millimeters, such as about 1.1 micrometers to about 10 micrometers, such as about 10 micrometers to about 50 micrometers, such as about 50 micrometers to about 200 micrometers, such as about 200 micrometers to about 500 micrometers, such as about 500 micrometers to about 1 millimeter on at least a portion of the first major surface or the second major surface of the semiconductor workpiece. In some examples, the strain altering portion may have a thickness that is in a range of about 0.1% to about 10%, such as about 10% to about 50%, such as about 50% to about 99.9% of the total thickness of the workpiece. In some examples, the strain altering process is one or more of a grinding process, a lapping process, a polishing process, a chemical mechanical polishing process, an electrochemical mechanical polishing process, a laser-based process, an implantation process, a plasma etching process, a reactive ion etching process, a sputtering process, a spallation process, or an electrochemical process.

Grinding is a material removal process that is used to remove material from the semiconductor wafer. Grinding may be used to reduce a thickness of a semiconductor wafer. Grinding typically involves exposing the semiconductor wafer to an abrasive containing surface, such as grinding teeth on a grind wheel. Grinding may remove material of the semiconductor wafer through engagement with the abrasive surface.

Lapping is a precision finishing process that uses a loose abrasive in slurry form. The slurry typically includes coarser particles (e.g., largest dimension of the particles being greater than about 100 microns) to remove material from the semiconductor wafer. Lapping typically does not include engaging the semiconductor wafer with an abrasive-containing surface on the lapping tool (e.g., a wheel or disc having an abrasive-containing surface). Instead, the semiconductor wafer typically comes into contact with a lapping plate or a tile usually made of metal. Lapping typically provides better planarization of the semiconductor wafer relative to grinding.

Polishing is a process to remove imperfections and create a very smooth surface with a low surface roughness. Polishing may be performed using a slurry and a polishing pad. The slurry typically includes finer particles relative to lapping, but coarser particles relative to chemical mechanical planarization (CMP). Polishing typically provides better planarization of the semiconductor wafer relative to grinding.

CMP is a type of fine or ultrafine polishing, typically used to produce a smoother surface ready, for instance, for epitaxial growth of layers on the semiconductor wafer. CMP may be performed chemically and/or mechanically to remove imperfections and to create a very smooth and flat surface with low surface roughness. CMP typically involves changing the material of the semiconductor through a chemical process (e.g., oxidation) and removing the new material from the semiconductor wafer through abrasive contact with a slurry and/or other abrasive surface or polishing pad (e.g., oxide removal). In CMP, the abrasive elements in the slurry typically remove the product of the chemical process and do not remove the bulk material of the semiconductor wafer, often leaving very low subsurface damage.

One example aspect of the present disclosure is directed toward a method for processing a silicon carbide semiconductor wafer. The method includes providing a silicon carbide semiconductor wafer having a first major surface and a second major surface. The method includes performing a strain altering process to produce an altered strain state in the silicon carbide semiconductor wafer. The method includes performing a subsequent fabrication process, wherein the subsequent fabrication process is a different type of process relative to the strain altering process. A different type of process may be a process that invokes different methods of affecting change on the workpiece. For instance, ion implantation is a different type of process relative to a surface processing operation. A chemical process is a different type of process relative to a laser-based operation.

In some examples, the strain altering process induces or relieves a stress in the silicon carbide semiconductor wafer. In some examples, the stress includes a stress in a radial direction toward a center portion of the silicon carbide semiconductor wafer. In some examples, the stress includes a stress in a radial direction toward a peripheral portion of the silicon carbide semiconductor wafer. In some examples, the altered strain state results from a compressive stress in a circumferential direction on the first major surface or the second major surface. In some examples, the altered strain state results from a tensile stress in a circumferential direction on the first major surface or the second major surface. In some examples, the stress includes a stress in an axial direction of the silicon carbide semiconductor wafer. In some examples, the stress includes a compressive stress or a tensile stress. In some examples, the altered strain state is configured to at least partially offset a deformation induced in the silicon carbide semiconductor wafer in the subsequent fabrication process. In some examples, the strain altering process is a surface processing operation, such as one or more of a grinding process, a lapping process, a polishing process, a chemical mechanical polishing process, or an electrochemical mechanical polishing process.

In some examples, the strain altering process includes applying a stimulus to the silicon carbide semiconductor wafer. In some examples, the stimulus includes an external force, a fluid pressure, a radiation exposure, a temperature change, or exposure to a magnetic field.

In some examples, the strain altering process includes a first strain altering process performed on at least a portion of the first major surface and a second strain altering process performed on at least a portion the second major surface. In some examples, the first strain altering process differs from the second strain altering process.

In some examples, the strain altering process is a laser-based process performed on at least a portion of the first major surface or the second major surface. In some examples, the laser-based process is one or more of a laser-based ablation process, a laser-based recrystallization process, or laser-based damage-inducing process.

In some examples, the strain altering process is a chemical process performed on at least a portion of the first major surface or the second major surface. In some examples, the chemical process is one or more of an electrochemical process, a chemical diffusion process, or an etching process.

In some examples, the strain altering process is a thermal process performed on at least a portion of the first major surface or the second major surface. In some examples, the thermal process is one or more of an annealing process, a relaxation process, a sublimation process, a melting process, or an evaporative process.

In some examples, the strain altering process is an ion-based process performed on at least a portion of the first major surface or the second major surface. In some examples, the ion-based process is one or more of an ion implantation process, an ion milling process, or a sputtering process.

In some examples, the strain altering process produces a strain altering portion on the silicon carbide semiconductor wafer. In some examples, the strain altering portion has a thickness in a range of about 0.1% to about 10% of a total thickness of the silicon carbide semiconductor wafer.

In some examples, one or more material properties of the silicon carbide semiconductor wafer in the strain altering portion includes a radial or axial gradient within a subsurface region of the silicon carbide semiconductor wafer. In some examples, one or more material properties of the silicon carbide semiconductor wafer in the strain altering portion includes a tangential gradient that is orthogonal to a radial direction within a subsurface region of the silicon carbide semiconductor wafer. In some examples, the one or more material properties include a coefficient of thermal expansion, a piezoelectric coefficient, an absorption coefficient, a defect density, a concentration of impurities, or a chemical reactivity.

In some examples, the strain altering process includes providing a material to at least a portion of the first major surface or the second major surface. In some examples, the strain altering process includes providing a material to at least a peripheral portion of the first major surface or the second major surface. In some examples, providing the material may include one or more of an adhesive attachment, sintering-based attachment, or proximity adhesion attachment.

In some examples, the subsequent fabrication process includes a grinding process, a lapping process, a polishing process, a deposition process, an epitaxial process, a doping process, an oxidation process, an annealing process, a dopant activation process, a curing process, a metallization process, a lithography process, or a device formation process. In some examples, the method includes further altering the strain state after the subsequent fabrication process.

Another example aspect of the present disclosure is directed toward a method for processing a silicon carbide semiconductor wafer. The method includes providing a silicon carbide semiconductor wafer having a first major surface and a second major surface. The method includes performing a surface processing operation on the first major surface to produce an altered strain state of the wafer. The method includes performing a deposition process on the second major surface. The method includes performing an implantation process on the second major surface. The altered strain state at least partially compensates for a deformation induced by the deposition process or the implantation process.

In some examples, the surface processing operation induces a stress in the silicon carbide semiconductor wafer. In some examples, the stress includes a stress in a radial direction toward a center portion of the silicon carbide semiconductor wafer. In some examples, the stress includes a stress in a radial direction toward a peripheral portion of the silicon carbide semiconductor wafer. In some examples, the stress includes a stress in an axial direction of the silicon carbide semiconductor wafer. In some examples, the stress includes a compressive stress or a tensile stress.

In some examples, the surface processing operation is one or more of a grinding process, a lapping process, a polishing process, a chemical mechanical polishing process, or an electrochemical mechanical polishing process. In some examples, the first major surface is a carbon face and the second major surface is a silicon face. In some examples, the deposition process is an epitaxial growth process wherein epitaxial layers are deposited on at least a portion of the first major surface or the second major surface.

Another example aspect of the present disclosure is directed toward a silicon carbide semiconductor wafer. The silicon carbide semiconductor wafer includes a first major surface and a second major surface. The silicon carbide semiconductor wafer includes a strain altering portion on at least one of the first major surface or the second major surface. The strain altering portion is configured to alter a strain state of the first major surface or the second major surface when the silicon carbide semiconductor wafer is exposed to a stimulus.

In some examples, the stimulus includes one or more of an external force, a fluid pressure, a radiation exposure, a temperature change, or an exposure to a magnetic field. In some examples, the strain altering portion has a thickness that is in a range of about 0.1% to about 10% of a total thickness of the wafer.

In some examples, the strain altering portion is a surface processing operation defined portion. In some examples, the strain altering portion comprises a material provided on at least a portion of the first major surface, the second major surface, or a peripheral portion of the silicon carbide semiconductor wafer. In some examples, the material is attached to the semiconductor wafer using an adhesive attachment, sintering-based attachment, or proximity adhesion attachment.

In some examples, one or more material properties of the silicon carbide semiconductor wafer in the strain altering portion include a modification over a radial or axial gradient within a subsurface region of the silicon carbide semiconductor wafer. In some examples, the one or more material properties include one or more of a coefficient of thermal expansion, a piezoelectric coefficient, an absorption coefficient, or a chemical reactivity.

In some examples, the strain altering portion induces or relieves a stress on the semiconductor wafer. In some examples, the stress is a compressive stress or a tensile stress.

Another example aspect of the present disclosure is directed toward a method for processing a silicon carbide semiconductor wafer. The method includes providing a silicon carbide semiconductor wafer having a first major surface and a second major surface. The method includes performing a first process on the first major surface. During performing of the first process, the method includes performing a second process on the second major surface. One or more stresses induced or relieved by the first process are at least partially offset by one or more stresses induced or relieved by the second process.

In some examples, the first process is an implantation process. In some examples, the second process includes a chemical process. In some examples, the chemical process includes one or more of an electrochemical process, a diffusion process, or an etching process. In some examples, the first process and the second process are performed in a same process chamber.

Another example aspect of the present disclosure is directed toward a method for processing a silicon carbide semiconductor wafer. The method includes providing a silicon carbide semiconductor wafer having a first major surface and a second major surface. The method includes performing a first process on the first major surface. The method includes performing a second process on the second major surface. The first process and the second process induce balanced stresses on the silicon carbide semiconductor wafer. The first process and the second process reduce deformation of the silicon carbide semiconductor wafer in subsequent fabrication processes.

In some examples, the first process is the same as the second process. In some examples, the first process is different from the second process. In some examples, the first process comprises an implantation process and the second process includes a surface processing operation. In some examples, the first process and the second process each include an implantation process. In some examples, the implantation process comprises implanting or diffusing a metal, such as antimony, nickel, or chromium by non-limiting example, in the silicon carbide semiconductor wafer.

Aspects of the present disclosure provide technical effects and benefits. For instance, performing a strain altering or stress altering process on a workpiece allows the bulk stresses of workpieces to impact fabrication operations to a lesser extent, allowing greater throughput and reduced processing costs. Processing times for stress altering operations can be reduced, as a process will not need to be altered to compensate for surface irregularities and faster processes may be used. Further, the quality of the device formed can be improved by tuning the surface of the workpiece to the fabrication process. Additionally, strain altering or pre-stressing a workpiece surface may allow robotic handling of the workpiece to be efficient and streamlined as control over the surface of the workpiece reduces unintentional interactions with a robotic handler. Altering stress or strain in a workpiece surface may lessen constraints relating to surface parameters in a crystal growth process or separation processes of bulk crystalline materials (e.g., boules). Altering strain or altering stress in a workpiece surface may provide better control of thermal uniformity and thermal gradients during processing operations.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, structure, region, or substrate is referred to as being “on” or extending “onto” another element, it may be directly on or extend directly onto the other element or intervening elements may also be present and may be only partially on the other element. In contrast, when an element is referred to as being “directly on” or extending “directly onto” another element, there are no intervening elements present, and may be partially directly on the other element. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

As used herein, a first structure “at least partially overlaps” or is “overlapping” a second structure if an axis that is perpendicular to a major surface of the first structure passes through both the first structure and the second structure. A “peripheral portion” of a structure includes regions of a structure that are closer to a perimeter of a surface of the structure relative to a geometric center of the surface of the structure. A “center portion” of the structure includes regions of the structure that are closer to a geometric center of the surface of the structure relative to a perimeter of the surface. “Generally perpendicular” means within 15 degrees of perpendicular. “Generally parallel” means within 15 degrees of parallel.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the invention are described with reference to semiconductor layers and/or regions which are characterized as having a conductivity type such as n type or p type, which refers to the majority carrier concentration in the layer and/or region. Thus, n type material has a majority equilibrium concentration of negatively charged electrons, while p type material has a majority equilibrium concentration of positively charged holes. Some material may be designated with a “+” or “−” (as in n+, n−, p+, p−, n++, n−−, p++, p−−, or the like), to indicate a relatively larger (“+”) or smaller (“−”) concentration of majority carriers compared to another layer or region. However, such notation does not imply the existence of a particular concentration of majority or minority carriers in a layer or region.

In the drawings and specification, there have been disclosed typical embodiments and, although specific terms are employed, they are used in a generic and descriptive sense only and not for purposes of limitation of the scope set forth in the following claims.

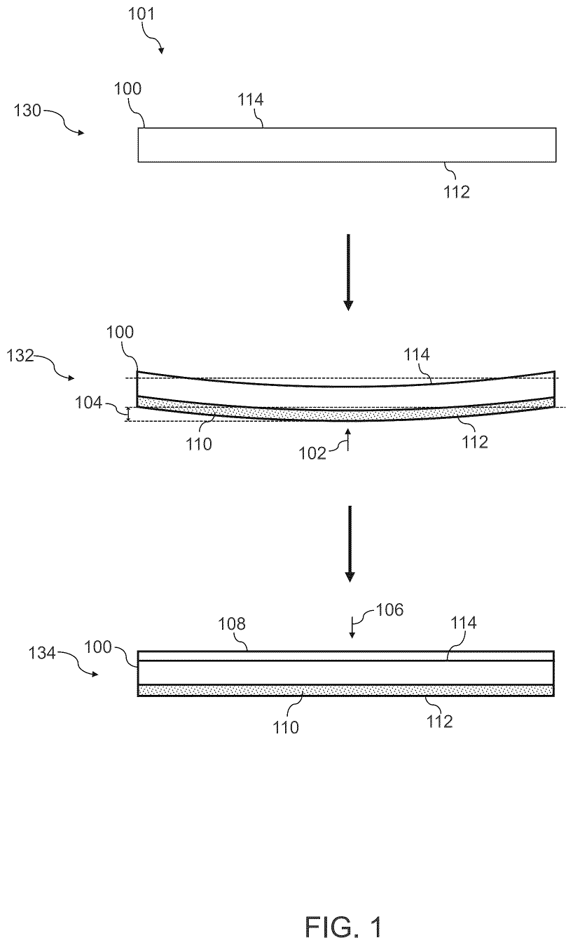

FIG. 1 depicts an example method 101 for processing a silicon carbide semiconductor wafer 100. At 130, the method 101 includes providing a wafer 100 with a first major surface 112 and a second major surface 114.

At 132, the method 101 includes performing a strain altering process 102, represented by an arrow, on the first major surface 112. The strain altering process 102 may produce a strain altering portion 110 through the first major surface 112 of the wafer 100. The strain altering portion 110 may induce or relieve a stress in the wafer 100. In some examples, the stress may act as a compressive stress or a tensile stress. For instance, the stress may be imparted or relieved in a radial direction toward a center portion of the silicon carbide semiconductor wafer. In some examples, the stress may be imparted or relieved in a radial direction toward a peripheral portion of the silicon carbide semiconductor wafer. In some examples, the stress may be imparted or relieved in an axial direction of the silicon carbide semiconductor wafer.

In some examples, the strain altering process 102 is one or more of a surface processing operations, such as one or more of a grinding process, a lapping process, a polishing process, a chemical mechanical polishing process, a laser-based process, an implantation process, a plasma etching process, a reactive ion etching process, a sputtering process, a spallation process, an electrochemical process or an electrochemical mechanical polishing process.

In some examples, the strain altering process 102 produces the strain altering portion 110 having a thickness that is in a range of about 0.1% to about 10%, such as about 10% to about 50%, such as about 50% to about 99.9% of the total thickness of the workpiece. For example, the strain altering process 102 that is a grinding process, a lapping process, a polishing process, a chemical mechanical polishing process, a laser-based process, an implantation process, a plasma etching process, a reactive ion etching process, a sputtering process, a spallation process, an electrochemical process, or an electrochemical mechanical polishing process may stress the strain altering portion 110 in a plastic deformation regime (e.g., permanent deformation regime) such that the bonding configuration of the strain altering portion 110 is altered.

In some examples, the strain altering process 102 is a laser-based process performed on at least a portion of the first major surface 112. In some embodiments, the laser-based process is one or more of a laser-based ablation process, a laser-based recrystallization process, or laser-based damage-inducing process. In some embodiments, the strain altering process 102 that is a laser-based process may alter the microstructure of the strain altering portion 110 by depositing energy in at least a portion of the strain altering portion 110. A microstructural change of the strain altering portion 110, as compared to the microstructure of the wafer 100 bulk that remains unchanged, may alter material properties of the strain altering portion 110 and the mechanical properties of the wafer 100. For instance, an absorption coefficient, a coefficient of thermal expansion, an elastic modulus, a yield strength, or other material property may be altered through a microstructural change.

In some examples, the strain altering process 102 is a chemical process performed on at least a portion of the first major surface 112 or the second major surface 114. In some embodiments, the chemical process is one or more of an electrochemical process, a wet etching process, or a dry etching process. In some examples, the strain altering process 102 that is the chemical process may alter the microstructure and/or the surface of the strain altering portion 110. For instance, a chemical process may alter an impurity concentration, a defect density, or otherwise remove or deposit material to the strain altering portion 110. A microstructural change of the strain altering portion 110, as compared to the microstructure of the wafer 100 bulk that remains unchanged, may alter material properties of the strain altering portion 110 and the mechanical properties of the wafer 100. For instance, an absorption coefficient, a coefficient of thermal expansion, an elastic modulus, a yield strength, or other material property may be altered through a microstructural change.

In some examples, the strain altering process 102 is a thermal process performed on at least a portion of the first major surface 112 or the second major surface 114. In some embodiments, the strain altering process 102 that is a thermal process is one or more of an annealing process, a rapid annealing process, a relaxation process, a sublimation process, a melting process, or an evaporative process. The strain altering process 102 may provide an energetic incentive to restructure atoms within the crystalline lattice of the strain altering portion 110 that alters the mechanical properties of the wafer 100. For instance, a thermal process may provide an energetic incentive to reduce or otherwise alter defects within the crystal lattice of the strain altering portion 110, altering the strain state 104 of the wafer 100.

In some examples, the strain altering process 102 is an ion-based process performed on at least a portion of the first major surface 112 or the second major surface 114. In some embodiments, the strain altering process 102 that is an ion-based process is one or more of an ion implantation process, an ion milling process, or a sputtering process. For example, an ion-based process may impart damage to at least a portion of the first major surface 112, altering internal stresses in the wafer 100 and the strain state 104 of the wafer 100.

In some examples, the strain-altering process 102 provides the strain altering portion 104 through a material provided on at least a portion of the first major surface 112, the second major surface 114, or a peripheral portion of the silicon carbide semiconductor wafer 100. In some examples, the material is attached to the semiconductor wafer using an adhesive attachment, sintering-based attachment, or proximity adhesion attachment.

An altered strain state 104, represented by a vertical deformation of the wafer 100 resulting from the strain altering process 102, may modify the mechanical behavior of the workpiece in a subsequent fabrication process 106. In some embodiments, such as the embodiment depicted in FIG. 1, the strain altering portion 110 may provide the altered strain state 104 through the first major surface 112 such that the first major surface 112 forms a convex shape. In some embodiments, a counterforce may act on at least a portion of the wafer 100 such that the altered strain state 104 forms a generally flat surface. For instance, imparting the altered strain state 104 through the first major surface 112 while hindering physical deformation of the wafer 100, such as with an external counterforce, an attached material that hinders deformation, or other process that inhibits deformation through internal stress (e.g., alterations to the crystal lattice to prevent deformation, for instance), may allow the wafer 100 to exhibit the altered strain state 104 where deformation is otherwise controlled in or by the processing environment.

At 134, the method 101 includes performing the subsequent fabrication process 106, represented by an arrow, on at least one of the first major surface 112 or the second major surface 114. The subsequent fabrication process 106 may be a different type of process relative to the strain altering process 102. For example, the strain altering process may be a grinding process that induces the altered strain state 104, and the subsequent fabrication process 106 may provide the wafer 100 with one or more additional layers 108 required for device formation, such as one or more of an epitaxial layer or an implantation region. The subsequent fabrication process 106 may provide a stress to the second major surface 114 of the wafer 100 such that the altered strain state 104 induced through the first major surface 112 compensates for a stress experienced by the second major surface 114 in the subsequent fabrication process 106. That is, the altered strain state 104, or deformation of the first major surface 112, may modify a mechanical behavior of the wafer 100 to compensate for stress experienced by the second major surface 114 in the subsequent fabrication process 106. The resulting shape of the first major surface 112 and the second major surface 114 following the subsequent fabrication process 106 may be modified by way of the altered strain state 104 resulting from the strain altering portion 110 of the first major surface 112. As such, the altered strain state 104 is configured to at least partially offset a deformation of the wafer 100 in the subsequent fabrication process 106.

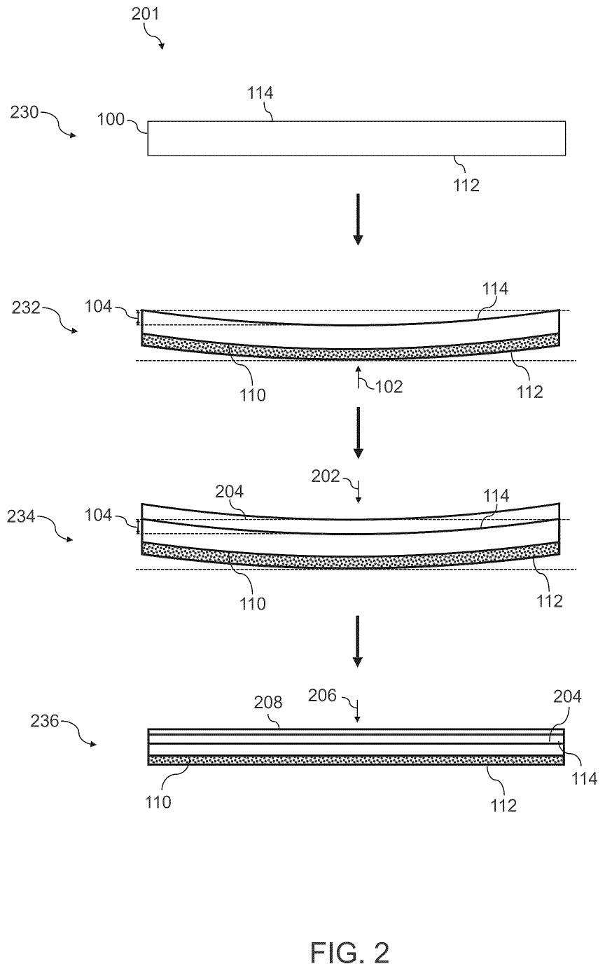

Referring now to FIG. 2, an example method 201 for processing the silicon carbide semiconductor wafer 100 is depicted. Like the example method 101 of FIG. 1, at 230 the method 201 of FIG. 2 includes providing the silicon carbide semiconductor wafer 100 with a first major surface 112 and a second major surface 114.

At 232, the method 201 includes performing the strain altering process 102, represented by an arrow, on at least a portion of the first major surface 112. The strain altering process 102 may be a surface processing operation, such as one or more of one or more of a grinding process, a lapping process, a polishing process, a chemical mechanical polishing process, or an electrochemical mechanical polishing process. The strain altering process may induce the altered strain state 104 through the strain altering portion 110 such that a stress is induced in the silicon carbide semiconductor wafer 100 as a result of the strain altering process 102. In some examples, the stress may act as a compressive stress or a tensile stress. The stress may be imparted in a radial direction toward a center portion of the silicon carbide semiconductor wafer. In some examples, the stress may be imparted in a radial direction toward a peripheral portion of the silicon carbide semiconductor wafer. In some examples, the stress may be imparted in an axial direction of the silicon carbide semiconductor wafer.

At 234, the method 201 includes performing a deposition process 202 on the second major surface 114. The deposition process 202 may deposit an epitaxial layer 204 required for subsequent fabrication processes.

At 236, the method 201 includes performing an implantation process 206 on the epitaxial layer 204 on the second major surface 114. As depicted in FIG. 2, the altered strain state 104 may at least partially compensate for a deformation induced by the deposition process 202 or the implantation process 206 such that a desired strain state (e.g., shape) results from the deposition process 202 and/or the implantation process 206. In some examples, the first major surface 112 is a carbon face and the second major surface 114 is a silicon face.

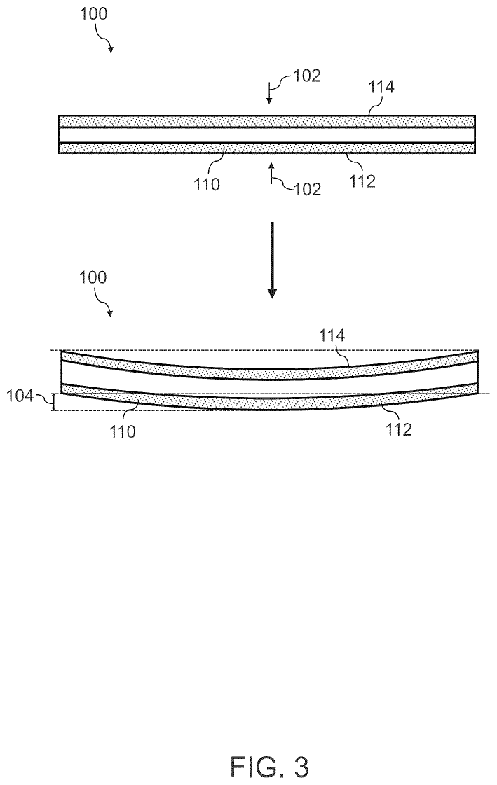

FIG. 3 depicts the wafer 100 having undergone the strain altering process 102 on the first major surface 112 and the second major surface 114. In some examples, the strain altering process 102 may include a stimulus 302, represented by an arrow, that induces the altered strain state 104 in the wafer. In some embodiments, the stimulus 302 may be one or more of an external force, a fluid pressure, a radiation exposure, a temperature change, or an exposure to a magnetic field. The strain altering process 102 may alter chemical, optical, electronic, or mechanical properties of the strain altering portion 110, which in turn may alter the internal stresses of the wafer 100 in response to the stimulus 302. As such, the strain altering portion 110 is configured to alter the strain state 104 of the first major surface 112 or the second major surface 114 when the wafer 100 is exposed to the stimulus 302.

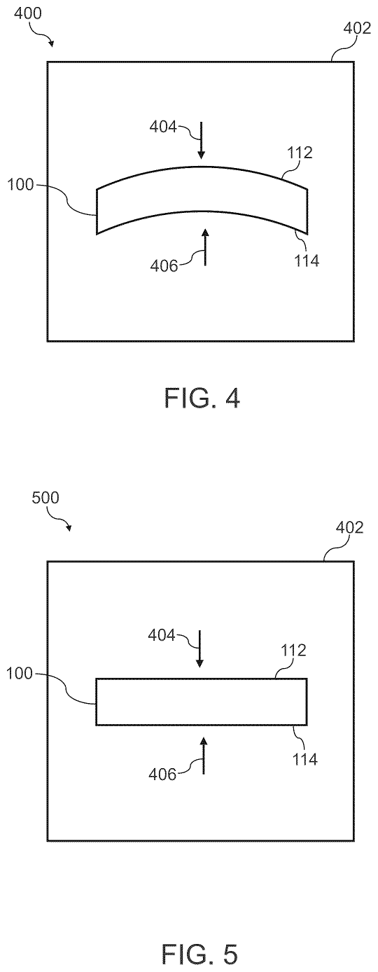

FIG. 4 depicts an example method 400 for processing a silicon carbide semiconductor wafer 100. The wafer 100 having the first major surface 112 and the second major surface 114 is provided to a process chamber 402. A first process 404 is performed on the first major surface 112. The first process 404 may be, for example, an implantation process, deposition process, epitaxy process, etc. While performing the first process 404, a second process 406 may be performed on the second major surface 114 where one or more stresses induced or relieved by the first process 404 are at least partially offset by one or more stresses induced or relieved by the second process 406. The second process 406 may be, for instance, a chemical process. The chemical process may include one or more of an electrochemical process, a diffusion process, or an etching process. The first process 404 and the second process 406 may be performed in the same process chamber 402. In this manner, the strain state of the wafer 100 may be altered in situ as a process progresses such that the strain state of the wafer 100 improves shape control during a process.

FIG. 5 depicts an example method 500 of processing a wafer 100. The wafer 100 having the first major surface 112 and the second major surface 114 is provided to the process chamber 402. The first process 402 is performed on the first major surface 112. The second process 504 is performed on the second major surface 114. The first process 402 and the second process 404 are performed such that balanced stresses are induced on the wafer 100, that is, the wafer 100 does not experience an alteration to the shape of the wafer 100. The first process 402 and the second process 404 may reduce deformation of the wafer 100 in a subsequent fabrication process. The first process 402 may be the same as the second process. For instance, the first process 402 and the second process 404 may each include an implantation process. The implantation process may include implanting or diffusing antimony, nickel, or chromium by non-limiting example in the wafer 100 to alter the crystal lattice of the wafer 100 and increase resistance to deformation. In some examples, the first process 404 is different from the second process 406. The first process 404 may include an implantation process and the second process 406 may include a surface processing operation (e.g., one or more of a grinding process, a lapping process, a polishing process, a chemical mechanical polishing process, or an electrochemical mechanical polishing process).

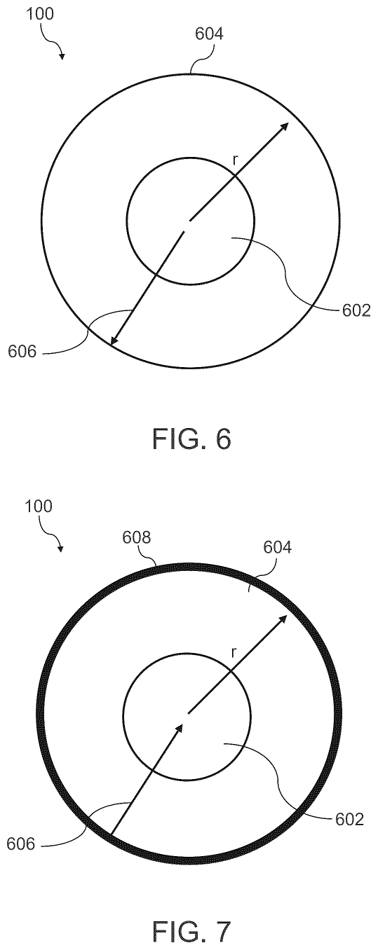

FIGS. 6 and 7 depict a plan view of the wafer 100 according to aspects of the present disclosure. FIGS. 6 and 7 depict a top view of the wafer 100 with radius r. The wafer 100 has a central portion 602 and a peripheral portion 604. Altering the stress may include a strain altering process that produces the shaped surface region performed uniformly on both the central portion 602 and the peripheral portion 604 of the wafer 100. In some embodiments, altering the stress includes the strain altering process performed on one of the central portion 602 or the peripheral portion 604 of the wafer 100. In embodiments where the strain altering process is performed on the peripheral portion 604 of the wafer 100, internal stresses result in the deformation (e.g., a stress) occurring at the peripheral portion of the wafer 100, resulting in a compressive force 606 (e.g., a compressive stress) from the central portion 602 of the wafer 100 to the peripheral portion 604 of the wafer 100. In some embodiments, the compressive force 606 (e.g., a compressive stress) may act from the peripheral portion 604 towards the central portion 602.

For example, in FIG. 7, the compressive force 606 acts from the peripheral portion 604 towards the central portion 602. The compressive force 606 may be due to the attachment of a material 608 on or along the peripheral portion of the wafer 100.

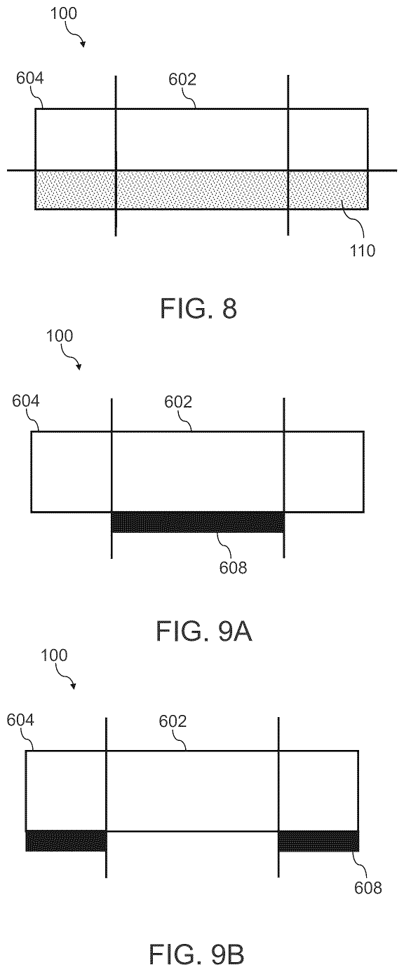

FIG. 8 depicts a cross-sectional view of the wafer 100 with the strain altering portion 110 modifying a surface of the wafer 100 to a depth. In some embodiments, the strain altering portion 110 may have a thickness that is in a range of about 0.1% to about 10% or about 10% to about 50% or about 50% to about 99.9% of the total thickness of the workpiece.

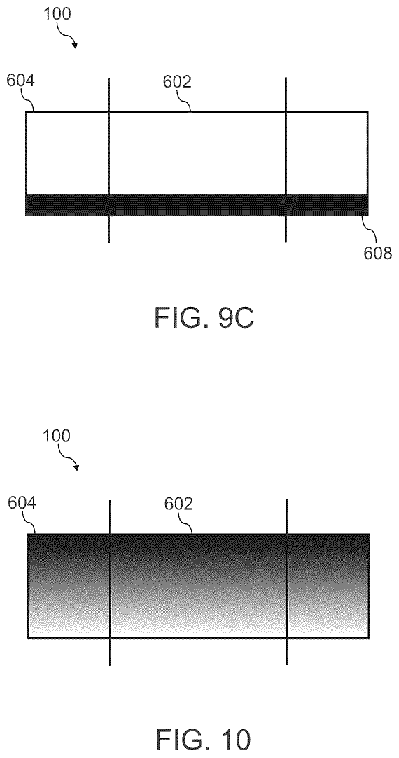

FIGS. 9A, 9B, and 9C depict a cross-sectional view of the wafer 100 with the attached material 608. The attached material 608 may be included on the central portion 602 of the wafer 100 as in FIG. 9A, the peripheral portion 604 of the wafer 100 as in 9B, on both the central portion 602 and the peripheral portion 604 as in 9C, or in a configuration such that the attached material 608. In some embodiments, the strain altering portion 110 or the attached material 608 may be included on only one of the peripheral portion 604 or the central portion 602 of the wafer 100.

FIG. 10 depicts a cross-sectional view of the wafer 100 such that the strain altering process applies a gradient of property and/or microstructure related alterations through the bulk of the wafer 100. That is, the one or more material properties may be altered uniformly to a specified depth to produce the strain altering portion 110, or, in some embodiments, the one or more material properties may be altered along a gradient through the wafer 100. In some embodiments the one or more material properties may be altered to a greater extent towards an upper portion of the wafer 100 with respect to a lower portion of the wafer 100. In some embodiments, the one or more material properties may be altered to a greater extent towards the lower portion of the wafer 100 with respect to the upper portion of the wafer 100. In some embodiments, the alteration of one or more material properties of the wafer 100 may occur along a radial gradient. That is, in some embodiments, the one or more material properties may be altered to a greater extent at a peripheral portion 604 of the wafer 100 and reduce toward the central portion 602 of the wafer 100. In some embodiments, the one or more material properties may be altered to a greater extent at a central portion 602 of the wafer 100 and reduce toward a peripheral portion 604 of the wafer 100. In some embodiments, the one or more material properties may include one or more of an alteration of a coefficient of thermal expansion, a piezoelectric coefficient, an absorption coefficient, a defect density, a concentration of impurities, or a chemical reactivity that alter the stress in response to the stimulus.

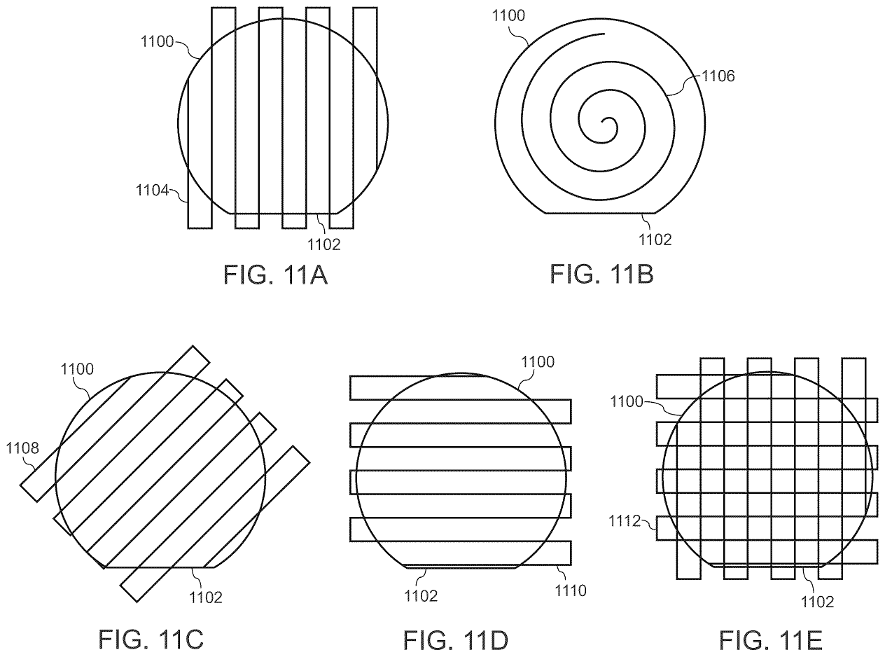

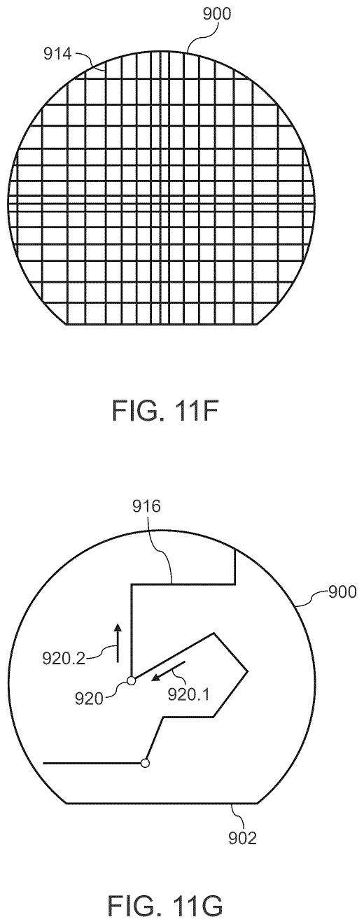

According to aspects of the present disclosure, one or more lasers may scan the surface of a workpiece in any suitable pattern to implement laser alteration of material. FIGS. 11A through 11G depict example scan patterns 1104 of a laser on an example wafer 1100 (e.g., silicon carbide semiconductor wafer) according to example embodiments of the present disclosure. The scan pattern depicted in FIG. 11A comprises a plurality of parallel scans or passes in a direction generally perpendicular to, for instance, a flat 1102 of the semiconductor wafer 1100.

FIGS. 11A through 11G depict an example scan pattern 1106 on the wafer 1100 (e.g., silicon carbide semiconductor wafer) according to example embodiments of the present disclosure. The scan pattern 1106 depicted in FIG. 11B comprises a spiral scan pattern on a surface of the wafer 1000.

FIG. 11C depicts an example scan pattern 1108 on an example semiconductor wafer 900 (e.g., silicon carbide semiconductor wafer) according to example embodiments of the present disclosure. The scan pattern 1106 depicted in FIG. 11C comprises a plurality of generally parallel scans or passes in a direction that is angled (not generally perpendicular and not generally parallel) to, for instance, a flat 1102 of the semiconductor wafer 1100.

FIG. 11D depicts an example scan pattern 1110 on an example semiconductor wafer 900 (e.g., silicon carbide semiconductor wafer) according to example embodiments of the present disclosure. The scan pattern 1110 depicted in FIG. 11D comprises a plurality of generally parallel scans or passes in a direction that is generally parallel to, for instance, a flat 1102 of the semiconductor wafer 1100.

FIG. 11E depicts an example scan pattern 1112 on an example semiconductor wafer 1100 (e.g., silicon carbide semiconductor wafer) according to example embodiments of the present disclosure. The scan pattern 1112 depicted in FIG. 11E comprises a plurality of generally parallel scans or passes and a plurality of generally perpendicular scans or passes to, for instance, a flat 1102 of the semiconductor wafer 1100.

FIG. 11F depicts an example scan pattern 1114 on an example semiconductor wafer 1100 (e.g., silicon carbide semiconductor wafer) according to example embodiments of the present disclosure. The scan pattern 1112 depicted in FIG. 11F comprises a plurality of generally parallel scans or passes and a plurality of generally perpendicular scans or passes to, for instance, a flat 1102 of the semiconductor wafer 1100. The scan pattern 1114 may involve a scan pattern with irregular spacing between generally parallel scans and generally perpendicular scans.

Other suitable laser scan patterns may be used without deviating from the scope of the present disclosure. For instance, the laser scan pattern may be an irregular or a random scan pattern. As additional non-limiting examples, the laser scan pattern may be a spot pattern, non-continuous pattern, zig zag pattern, herringbone pattern, chevron pattern, array of polygons, concentric circles, or other suitable pattern.

For instance, FIG. 11G depicts an example non-continuous scan pattern 1116 on an example semiconductor wafer 1100 (e.g., silicon carbide semiconductor wafer) according to example embodiments of the present disclosure. The scan pattern 1116 depicted in FIG. 11G includes a plurality of discrete and separated scan points 1114.1, 1114.2, . . . 1114.n on the semiconductor wafer 1100. The laser scan pattern 1116 can provide emission of the laser on or between the discrete points 1114.1, 1114.2, . . . 1114.n to remove local topographical areas. The discrete points can be in a regular pattern or in a scattered, irregular pattern.

Example aspects of the present disclosure are set forth below. Any of the below features or examples may be used in combination with any of the embodiments or features provided in the present disclosure.

In an aspect, the present disclosure provides an example method. In some implementations, the example method includes providing a silicon carbide semiconductor wafer having a first major surface and a second major surface. In some implementations, the example method includes performing a strain altering process to produce an altered strain state in the silicon carbide semiconductor wafer. In some implementations, the example method includes performing a fabrication process, wherein the fabrication process is a different type of process relative to the strain altering process, wherein the altered strain state at least partially compensates for stress or strain induced in the silicon carbide semiconductor wafer in the fabrication process.

In some implementations of the example method, the strain altering process induces or relieves a stress in the silicon carbide semiconductor wafer.

In some implementations of the example method, the stress includes a stress in a radial direction toward a center portion of the silicon carbide semiconductor wafer.

In some implementations of the example method, the stress includes a stress in a radial direction toward a peripheral portion of the silicon carbide semiconductor wafer.

In some implementations of the example method, the stress includes a stress in an axial direction or a circumferential direction of the silicon carbide semiconductor wafer.

In some implementations of the example method, the strain altering process is a shaping process.

In some implementations of the example method, the stress includes a compressive stress or a tensile stress.

In some implementations of the example method, the altered strain state is configured to at least partially offset a deformation induced in the silicon carbide semiconductor wafer in the fabrication process.

In some implementations of the example method, the strain altering process includes applying a stimulus to the silicon carbide semiconductor wafer.

In some implementations of the example method, the stimulus includes an external force, a fluid pressure, a radiation exposure, a temperature change, or exposure to a magnetic field.

In some implementations of the example method, the strain altering process includes a first strain altering process performed on at least a portion of the first major surface and a second strain altering process performed on at least a portion the second major surface.

In some implementations of the example method, the first strain altering process differs from the second strain altering process.

In some implementations of the example method, the strain altering process is one or more of a grinding process, a lapping process, a polishing process, a chemical mechanical polishing process, or an electrochemical mechanical polishing process.

In some implementations of the example method, the strain altering process is a laser-based process performed on at least a portion of the first major surface or the second major surface.

In some implementations of the example method, the laser-based process is one or more of a laser-based ablation process, a laser-based recrystallization process, or laser-based damage-inducing process.

In some implementations of the example method, the strain altering process is a chemical process performed on at least a portion of the first major surface or the second major surface.

In some implementations of the example method, the chemical process is one or more of an electrochemical process, a diffusion process, or an etching process.

In some implementations of the example method, the strain altering process is a thermal process performed on at least a portion of the first major surface or the second major surface.

In some implementations of the example method, the thermal process is one or more of an annealing process, a relaxation process, a sublimation process, a melting process, or an evaporative process.

In some implementations of the example method, the strain altering process is an ion-based process performed on at least a portion of the first major surface or the second major surface.

In some implementations of the example method, the ion-based process is one or more of an ion implantation process, an ion milling process, or a sputtering process.

In some implementations of the example method, the strain altering process produces a strain altering portion on the silicon carbide semiconductor wafer.

In some implementations of the example method, the strain altering portion has a thickness in a range of about 0.1% to about 10% of a total thickness of the silicon carbide semiconductor wafer.

In some implementations of the example method, one or more material properties of the silicon carbide semiconductor wafer in the strain altering portion comprise a radial, axial, or circumferential gradient within a subsurface region of the silicon carbide semiconductor wafer.

In some implementations of the example method, the one or more material properties comprise a coefficient of thermal expansion, a piezoelectric coefficient, an absorption coefficient, a defect density, a concentration of impurities, or a chemical reactivity.

In some implementations of the example method, the strain altering process includes providing a material to at least a portion of the first major surface or the second major surface.

In some implementations of the example method, the strain altering process includes providing a material to at least a peripheral portion of the first major surface or the second major surface.

In some implementations of the example method, the fabrication process modifies a shape of the workpiece.

In some implementations of the example method, the fabrication process includes a grinding process, a lapping process, a polishing process, a deposition process, an epitaxial process, a doping process, an oxidation process, an annealing process, a dopant activation process, a curing process, a metallization process, a lithography process, or a device formation process.

In some implementations of the example method, the fabrication process is a subsequent fabrication process occurring after the strain altering process or a prior fabrication process performer before the strain altering process.

In an aspect, the present disclosure provides an example method. In some implementations, the example method includes providing a silicon carbide semiconductor wafer having a first major surface and a second major surface. In some implementations, the example method includes performing a surface processing operation on the first major surface to produce an altered strain state of the wafer. In some implementations, the example method includes performing a deposition process on the second major surface. In some implementations, the example method includes performing an implantation process on the second major surface. In some implementations, the altered strain state at least partially compensates for a deformation induced by the deposition process or the implantation process.

In some implementations of the example method, the surface processing operation induces a stress in the silicon carbide semiconductor wafer.

In some implementations of the example method, the stress includes a stress in a radial direction toward a center portion of the silicon carbide semiconductor wafer.

In some implementations of the example method, the stress includes a stress in a radial direction toward a peripheral portion of the silicon carbide semiconductor wafer.

In some implementations of the example method, the stress includes a stress in an axial direction of the silicon carbide semiconductor wafer.

In some implementations of the example method, the stress includes a stress in a circumferential direction of the silicon carbide semiconductor wafer.

In some implementations of the example method, the stress includes a compressive stress or a tensile stress.

In some implementations of the example method, the surface processing operation is one or more of a grinding process, a lapping process, a polishing process, a chemical mechanical polishing process, or an electrochemical mechanical polishing process.

In some implementations of the example method, the first major surface is a carbon face and the second major surface is a silicon face.

In some implementations of the example method, the deposition process is an epitaxial growth process wherein epitaxial layers are deposited on at least a portion of the first major surface or the second major surface.

In an aspect, the present disclosure provides an example silicon carbide semiconductor wafer. In some implementations, the example silicon carbide semiconductor wafer includes a first major surface and a second major surface. In some implementations, the example silicon carbide semiconductor wafer includes a strain altering portion on at least one of the first major surface or the second major surface, wherein the strain altering portion is configured to alter a strain state of the first major surface or the second major surface when the silicon carbide semiconductor wafer is exposed to a stimulus.

In some implementations of the example silicon carbide semiconductor wafer, the stimulus includes one or more of an external force, a fluid pressure, a radiation exposure, a temperature change, or an exposure to a magnetic field.

In some implementations of the example silicon carbide semiconductor wafer, the strain altering portion has a thickness that is in a range of about 0.1% to about 10% of a total thickness of the wafer.

In some implementations of the example silicon carbide semiconductor wafer, the strain altering portion is a surface processing operation defined portion.

In some implementations of the example silicon carbide semiconductor wafer, the strain altering portion includes a material provided on at least a portion of the first major surface, the second major surface, or a peripheral portion of the silicon carbide semiconductor wafer.

In some implementations of the example silicon carbide semiconductor wafer, the material is attached to the semiconductor wafer using an adhesive attachment, sintering-based attachment, or proximity adhesion attachment.

In some implementations of the example silicon carbide semiconductor wafer, one or more material properties of the silicon carbide semiconductor wafer in the strain altering portion comprise a radial, axial, or circumferential gradient within a subsurface region of the silicon carbide semiconductor wafer.

In some implementations of the example silicon carbide semiconductor wafer, the one or more material properties comprise one or more of a coefficient of thermal expansion, a piezoelectric coefficient, an absorption coefficient, or a chemical reactivity.

In some implementations of the example silicon carbide semiconductor wafer, the strain altering portion induces or relieves a stress on the semiconductor wafer.

In some implementations of the example silicon carbide semiconductor wafer, the stress is a compressive stress or a tensile stress.

In an aspect, the present disclosure provides an example method. In some implementations, the example method includes performing a first process on the first major surface. In some implementations, the example method includes during performing of the first process, performing a second process on the second major surface, wherein the second process is a different type of process relative to the first process. In some implementations, one or more stresses induced or relieved by the first process are at least partially offset by one or more stresses induced or relieved by the second process.

In some implementations of the example method, the first process is an implantation process.

In some implementations of the example method, the second process includes a chemical process.

In some implementations of the example method, the chemical process includes one or more of an electrochemical process, a diffusion process, or an etching process.

In some implementations of the example method, the first process and the second process are performed in a same process chamber.

In an aspect, the present disclosure provides an example method. In some implementations of the example method, the method includes providing a silicon carbide semiconductor wafer having a first major surface and a second major surface. In some implementations of the example method, the method includes performing a first process on the first major surface. In some implementations of the example method, the method includes performing a second process on the second major surface. In some implementations of the example method, the method includes wherein the first process and the second process induce balanced stresses on the silicon carbide semiconductor wafer, wherein the first process and the second process reduce deformation of the silicon carbide semiconductor wafer in one or more fabrication processes.

In some implementations of the example method, the first process is the same as the second process.

In some implementations of the example method, the first process is different from the second process.

In some implementations of the example method, the first process includes an implantation process and the second process includes a surface processing operation.

In some implementations of the example method, the first process and the second process each comprise an implantation process.

In some implementations of the example method, the implantation process includes implanting or diffusing antimony in the silicon carbide semiconductor wafer.

In an aspect, the present disclosure provides an example method. In some implementations, the example method includes providing a silicon carbide semiconductor wafer having a first major surface and a second major surface. In some implementations, the example method includes performing a strain altering process to produce an altered strain state in the silicon carbide semiconductor wafer by adding or reducing stress to the semiconductor wafer. In some implementations, the strain altering process is one or more of a surface processing operation, laser-based process, chemical process, or a thermal process.

In some implementations of the example method, the strain altering process includes a surface processing operation, the surface process operation comprising one or more of a grinding process, a lapping process, a polishing process, a chemical mechanical polishing process, or an electrochemical mechanical polishing process.

In some implementations of the example method, the strain altering process includes the laser-based process, the laser-based process comprising one or more of a laser-based ablation process, a laser-based recrystallization process, or laser-based damage-inducing process.

In some implementations of the example method, the strain altering process includes the chemical process, the chemical process comprising one or more of an electrochemical process, a diffusion process, or an etching process.

In some implementations of the example method, the strain altering process includes the thermal process, the thermal process comprising one or more of an annealing process, a relaxation process, a sublimation process, a melting process, or an evaporative process.

While the present subject matter has been described in detail with respect to specific example embodiments thereof, it will be appreciated that those skilled in the art, upon attaining an understanding of the foregoing can readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A method for processing a silicon carbide semiconductor wafer, comprising:
providing a silicon carbide semiconductor wafer having a first major surface and a second major surface;
performing a strain altering process to produce an altered strain state in the silicon carbide semiconductor wafer; and
performing a fabrication process, wherein the fabrication process is a different type of process relative to the strain altering process, wherein the altered strain state at least partially compensates for stress or strain induced in the silicon carbide semiconductor wafer in the fabrication process.

2. The method of claim 1, wherein the strain altering process induces or relieves a stress in the silicon carbide semiconductor wafer.

3. The method of claim 2, wherein the stress comprises a stress in a radial direction toward a center portion of the silicon carbide semiconductor wafer or a stress in a radial direction towards a peripheral portion of the silicon carbide semiconductor wafer.

4. The method of claim 2, wherein the stress comprises a stress in an axial direction or a circumferential direction of the silicon carbide semiconductor wafer.

5. The method of claim 1, wherein the strain altering process is a shaping process.

6. The method of claim 1, wherein the altered strain state is configured to at least partially offset a deformation induced in the silicon carbide semiconductor wafer in the fabrication process.

7. The method of claim 1, wherein the strain altering process comprises applying a stimulus to the silicon carbide semiconductor wafer, wherein the stimulus comprises an external force, a fluid pressure, a radiation exposure, a temperature change, or exposure to a magnetic field.

8. The method of claim 1, wherein the strain altering process comprises a first strain altering process performed on at least a portion of the first major surface and a second strain altering process performed on at least a portion the second major surface.

9. The method of claim 8, wherein the first strain altering process differs from the second strain altering process.

10. The method of claim 1, wherein the strain altering process is one or more of a grinding process, a lapping process, a polishing process, a chemical mechanical polishing process, or an electrochemical mechanical polishing process.

11. The method of claim 1, wherein the strain altering process is a laser-based process performed on at least a portion of the first major surface or the second major surface.

12. The method of claim 1, wherein the strain altering process is a chemical process performed on at least a portion of the first major surface or the second major surface.

13. The method of claim 1, wherein the strain altering process is a thermal process performed on at least a portion of the first major surface or the second major surface.

14. The method of claim 1, wherein the strain altering process produces a strain altering portion on the silicon carbide semiconductor wafer.

15. The method of claim 14, wherein the strain altering portion has a thickness in a range of about 0.1% to about 10% of a total thickness of the silicon carbide semiconductor wafer.

16. The method of claim 14, wherein one or more material properties of the silicon carbide semiconductor wafer in the strain altering portion comprise a radial, axial, or circumferential gradient within a subsurface region of the silicon carbide semiconductor wafer, wherein the one or more material properties comprise a coefficient of thermal expansion, a piezoelectric coefficient, an absorption coefficient, a defect density, a concentration of impurities, or a chemical reactivity.

17. The method of claim 1, wherein the strain altering process comprises providing a material to at least a portion of the first major surface or the second major surface.

18. The method of claim 1, wherein the fabrication process includes a grinding process, a lapping process, a polishing process, a deposition process, an epitaxial process, a doping process, an oxidation process, an annealing process, a dopant activation process, a curing process, a metallization process, a lithography process, or a device formation process.

19. A method for processing a silicon carbide semiconductor wafer, comprising:
providing a silicon carbide semiconductor wafer having a first major surface and a second major surface;
performing a surface processing operation on the first major surface to produce an altered strain state of the wafer;
performing a deposition process on the second major surface; and
performing an implantation process on the second major surface;
wherein the altered strain state at least partially compensates for a deformation induced by the deposition process or the implantation process.

20. A silicon carbide semiconductor wafer, comprising:
a first major surface and a second major surface; and
a strain altering portion on at least one of the first major surface or the second major surface, wherein the strain altering portion is configured to alter a strain state of the first major surface or the second major surface when the silicon carbide semiconductor wafer is exposed to a stimulus.
